(19) United States
(12) Patent Application Publication
(10) Pub. No.: US 2025/0122371 A1
(43) Pub. Date: Apr. 17, 2025

(54) THERMOSETTING RESIN COMPOSITION, COVERLAY FILM, ADHESIVE SHEET, AND FLEXIBLE PRINTED CIRCUIT BOARD

(71) Applicant: Arisawa MFG. Co., Ltd., Niigata (JP)

(72) Inventors: Takashi GONDAIRA, Niigata (JP); Katsuhiko FURUKAWA, Niigata (JP); Toshiki MOROHASHI, Niigata (JP); Yuki ISHIKAWA, Niigata (JP)

(73) Assignee: Arisawa MFG. Co., Ltd., Niigata (JP)

(21) Appl. No.: 18/692,451

(22) PCT Filed: Oct. 18, 2021
(86) PCT No.: PCT/JP2021/038486

§ 371 Date: Mar. 15, 2024

(51) Int. Cl. C08L 63/04; C08G 18/44; C08G 59/24; C08G 59/40; C08K 3/22

(52) U.S. Cl. CPC C08L 63/04; C08G 18/44; C08G 59/245; C08G 59/4064; C08K 3/22; C08G 2170/00; C08K 2003/2227; C08L 2203/206; C08L 2205/025; C08L 2205/035; C08L 2207/53

(57) ABSTRACT

The present invention provides a thermosetting resin composition including: a solid epoxy resin that is solid at 25° C.; a non-solid epoxy resin that is non-solid at 25° C.; a fine particulate rubber dispersed in the non-solid epoxy resin; a curing agent; an inorganic filler; and a polycarbonate diol-derived polyurethane. In the thermosetting resin composition, the content of the fine particulate rubber is from 3 to 15 parts by mass with respect to the total parts by mass of the solid epoxy resin and the non-solid epoxy resin, the acid value of the polycarbonate diol-derived polyurethane is from 10 to 30 mg KOH/g, and the weight average molecular weight of the polycarbonate diol-derived polyurethane is from 15,000 to 60,000.

### BACKGROUND

### 1. Field of the Disclosure

The present disclosure relates to a thermosetting resin composition, a coverlay film, an adhesive sheet, and a flexible printed wiring board.

### 2. Discussion of the Background Art

Examples of sheet-like electronic materials to be included in electronic devices include coverlay films, adhesive sheets, and flexible printed wiring boards. Such electronic materials are required to have physical properties such as peeling strength (hereinafter, also referred to as “peel strength”), electrical properties such as electrical insulation reliability (hereinafter, also referred to as “migration properties”), heat resistance properties such as solder heat resistance, and flame-retardant properties, in a balanced manner (see, Patent Literature 1, for example).

### CITATION LIST

### Patent Literature

Patent Literature 1: Unexamined Japanese Patent Application Publication No. 2005-187810

### SUMMARY

### Technical Problem

In recent years, there has been a growing demand for sheet-like electronic materials that can be processed efficiently and easily, and that have an excellent electrical insulation reliability under harsh conditions. Being able to be processed efficiently and easily as used here refers to the ability to be processed by thermocompression bonding (hereinafter, also referred to as “quick pressing”) within a short period of time. Having an excellent electrical insulation reliability under harsh conditions refers to the fact that an excellent electrical insulation reliability is demonstrated, for example, in the evaluation of electrical insulation reliability under high stress conditions of 110° C., 85% RH, and DC 50V, namely, in the biased highly accelerated temperature and humidity stress test (BHAST).

The present disclosure has been made in view of the above-described circumstances, and an objective of the present disclosure is to provide a thermosetting resin composition, a coverlay film, an adhesive sheet and a flexible printed wiring board that can be processed by quick pressing and that have an excellent electrical insulation reliability in BHAST.

### Solution to Problem

As a result of intensive studies to achieve the above-mentioned objective, the present inventors have found out that the above-mentioned objective can be achieved by a thermosetting resin composition including: a solid epoxy resin that is solid at 25° C.; a non-solid epoxy resin that is non-solid at 25° C.; a fine particulate rubber dispersed in the non-solid epoxy resin; a curing agent; an inorganic filler; and a polycarbonate diol-derived polyurethane, wherein a content of the fine particulate rubber is from 3 to 15 parts by mass with respect to total parts by mass of the solid epoxy resin and the non-solid epoxy resin, an acid value of the polycarbonate diol-derived polyurethane is from 10 to 30 mg KOH/g, and a weight average molecular weight of the polycarbonate diol-derived polyurethane is from 15,000 to 60,000, thereby completing the present disclosure.

Specifically, the present disclosure is as follows.

[1] A thermosetting resin composition, including:
a solid epoxy resin that is solid at 25° C.;
a non-solid epoxy resin that is non-solid at 25° C.;
a fine particulate rubber dispersed in the non-solid epoxy resin;
a curing agent;
an inorganic filler; and
a polycarbonate diol-derived polyurethane, wherein
a content of the fine particulate rubber is from 3 to 15 parts by mass with respect to total parts by mass of the solid epoxy resin and the non-solid epoxy resin,
an acid value of the polycarbonate diol-derived polyurethane is from 10 to 30 mg KOH/g, and
a weight average molecular weight of the polycarbonate diol-derived polyurethane is from 15,000 to 60,000.

[2] The thermosetting resin composition according to the above-described [1], wherein the fine particulate rubber includes core-shell polymer particles.

[3] The thermosetting resin composition according to the above-described [1] or [2], wherein the fine particulate rubber and the non-solid epoxy resin are contained in an amount of from 15 to 40 parts by mass, when the total parts by mass of the solid epoxy resin and the non-solid epoxy resin is taken as 100 parts by mass.

[4] The thermosetting resin composition according to any one of the above-described [1] to [3], wherein the polycarbonate diol-derived polyurethane is contained in an amount of from 50 to 100 parts by mass, when the total parts by mass of the solid epoxy resin and the non-solid epoxy resin is taken as 100 parts by mass.

[5] The thermosetting resin composition according to any one of the above-described [1] to [4], wherein the inorganic filler is contained in an amount of from 60 to 150 parts by mass, when the total parts by mass of the solid epoxy resin and the non-solid epoxy resin is taken as 100 parts by mass.

[6] A coverlay film, including:
a base material; and
an adhesive layer laminated on one surface of the base material,
wherein an adhesive of the adhesive layer includes the thermosetting resin composition according to any one of the above-described [1] to [5].

[7] An adhesive sheet including the thermosetting resin composition according to any one of the above-described [1] to [5].

[8] A flexible printed wiring board, including:
a substrate on which wiring is formed; and
a coverlay film including:
   a base material; and
   an adhesive layer laminated on one surface of the base material, wherein
the coverlay film is provided such that the adhesive layer is in contact with the surface of the substrate on which the wiring is formed, and
the coverlay film is the coverlay film according to the above-described [6].

### Advantageous Effects of Invention

The present disclosure enables to provide a thermosetting resin composition, a coverlay film, an adhesive sheet, and a flexible printed wiring board that can be processed by quick pressing and that have an excellent electrical insulation reliability in BHAST.

### BRIEF DESCRIPTION OF THE DRAWING

FIG. 1 is a plan view illustrating a wiring pattern employed in a characteristic evaluation test of a flexible printed wiring board using the thermosetting resin composition according to the present disclosure.

### DETAILED DESCRIPTION OF THE PREFERRED EMBODIMENT

Embodiments for carrying out the present disclosure (hereinafter, each referred to as “embodiment”) are described below in detail. The following embodiments are examples for describing the present disclosure, and are not intended to limit the present disclosure to the contents described below. The present disclosure can be modified and implemented as appropriate without departing from the scope of the present disclosure.

### (Thermosetting Resin Composition)

The thermosetting resin composition according to the present disclosure is suitably used mainly as a resin composition for electronic materials such as a coverlay film, an adhesive sheet, and a flexible printed wiring board.

The thermosetting resin composition of an embodiment contains a solid epoxy resin that is solid at 25° C.; a non-solid epoxy resin that is non-solid at 25° C.; a fine particulate rubber dispersed in the non-solid epoxy resin; a curing agent; an inorganic filler; and a polycarbonate diol-derived polyurethane. In the thermosetting resin composition, the content of the fine particulate rubber is from 3 to 15 parts by mass with respect to the total parts by mass of the solid epoxy resin and the non-solid epoxy resin, the acid value of the polycarbonate diol-derived polyurethane is from 10 to 30 mg KOH/g, and the weight average molecular weight of the polycarbonate diol-derived polyurethane is from 15,000 to 60,000.

### (Epoxy Resins)

The epoxy resins to be contained in the thermosetting resin composition of the embodiment include both a solid epoxy resin that is solid at 25° C. and a non-solid epoxy resin that is non-solid at 25° C., from the viewpoint of allowing the thermosetting resin composition to be uniformly mixed, the viewpoint of spreading and filling the resins into fine grooves between wiring (hereinafter, also referred to as “wiring embeddability”), the viewpoint of increasing the electrical insulation reliability after curing of the thermosetting resin composition, and the viewpoint of imparting the heat resistance to the composition.

It is preferred that the solid epoxy resin that is solid at 25° C. have two or more epoxy groups within one molecule and have an epoxy equivalent of from 150 to 500 g/eq, and more preferably from 150 to 350 g/eq, from the viewpoint of increasing the reactivity, and the viewpoint of increasing the electrical insulation reliability after curing of the thermosetting resin composition. Examples of the epoxy resin include epoxy resins having an epoxy equivalent within the range described above, such as bisphenol A type epoxy resins, bisphenol F type epoxy resins, bisphenol S type epoxy resins, novolac type epoxy resins, amine type epoxy resins, biphenyl type epoxy resins and alicyclic epoxy resins. A bisphenol A type epoxy resin is preferred and a biphenyl type epoxy resin is more preferred, from the viewpoint of the electrical insulation reliability and flame retardancy. Two or more kinds of the epoxy resins may be used, as well. The solid epoxy resin that is solid at 25° C. may be dissolved in an organic solvent in advance, in order to facilitate mixing with other materials contained in the thermosetting resin composition. The epoxy equivalent of the epoxy resin can be measured in accordance with JIS K7236 2001.

The content of the solid epoxy resin that is solid at 25° C. is preferably from 60 to 85 parts by mass, when the total amount of the epoxy resins (the solid epoxy resin that is solid at 25° C. and the non-solid epoxy resin that is non-solid at 25° C.) contained in the thermosetting resin composition is taken as 100 parts by mass. When the content of the solid epoxy resin that is solid at 25° C. is within the range of from 60 to 85 parts by mass, the tackiness (stickiness) can be reduced, for example, in cases where the thermosetting resin composition is processed in the form of a sheet and the cured state of the thermosetting resin composition is set to a semi-cured state (Stage B). Further, the amount of air (air bubbles) mixed during the quick pressing can be reduced. The term “parts by mass” as used in the present disclosure refers to parts by mass in terms of non-volatile content. The “parts by mass in terms of non-volatile content” refers, for example, to parts by mass of a resin (non-volatile content) excluding one or more volatile components such as organic solvents contained in the resin. Further, the term “semi-cured state (Stage B)” refers to a state where the curing reaction of the thermosetting resin composition has proceeded halfway but not completely.

The non-solid epoxy resin that is non-solid at 25° C. refers to an epoxy resin that has fluidity at 25° C. It is preferred that the non-solid epoxy resin that is non-solid at 25° C. have two or more epoxy groups within one molecule and have an epoxy equivalent of from 100 to 400 g/eq, and more preferably from 150 to 350 g/eq, from the viewpoint of increasing the dispersibility of the fine particulate rubber, and the viewpoint of increasing the peel strength of a sheet-like electronic material including the thermosetting resin composition. Examples of the epoxy resin include epoxy resins having an epoxy equivalent within the range described above, such as bisphenol A type epoxy resins, bisphenol F type epoxy resins, phenol novolac type epoxy resins, amine type epoxy resins and alicyclic epoxy resins. Two or more kinds of the epoxy resins may be used, as well. A bisphenol A type epoxy resin is preferred and a phenol novolac type epoxy resin is more preferred, from the viewpoint of the heat resistance. Further, it is preferred to uniformly disperse the fine particulate rubber in the non-solid epoxy resin that is non-solid at 25° C. before the preparation of the thermosetting resin composition, from the viewpoint of obtaining physical properties such as the peel strength of a sheet-like electronic material including the thermosetting resin composition.

The content of the non-solid epoxy resin that is non-solid at 25° C. is preferably from 15 to 40 parts by mass, more preferably from 15 to 35 parts by mass, and still more preferably from 15 to 30 parts by mass, when the total amount of the epoxy resins (the solid epoxy resin that is solid at 25° C. and the non-solid epoxy resin that is non-solid at 25° C.) contained in the thermosetting resin composition is taken as 100 parts by mass. When the content of the non-solid epoxy resin that is non-solid at 25° C. is within the range of from 15 to 40 parts by mass, the peel strength of a sheet-like electronic material including the thermosetting resin composition can be maintained at a high level.

### (Fine Particulate Rubber)

The fine particulate rubber is preferably core-shell polymer particles each including a core layer and a shell layer covering the surface of the core layer.

The polymer constituting the core layer is a polymer having a rubber-like elasticity. Examples of the polymer having a rubber-like elasticity include a diene rubber, an acrylic rubber, a styrene rubber, and a polysiloxane rubber. The polymer constituting the core layer may include two or more kinds of the polymers having a rubber-like elasticity.

Examples of the polymer constituting the shell layer include a (co) polymer obtained by copolymerizing one or more components selected from the group consisting of a (meth)acrylic acid ester monomer, an aromatic vinyl monomer, a vinyl cyanide monomer, an unsaturated acid derivative, a (meth)acrylamide derivative and a maleimide derivative. The polymer constituting the shell layer is bonded to the polymer constituting the core layer by graft polymerization. This allows the shell layer to stably cover a part or the entirety of the surface of the core layer, making it possible to prevent the re-agglomeration of the core-shell polymer particles.

From the viewpoint of compatibility with epoxy resins, it is preferred that a functional group that reacts with the resins or the curing agent contained in the thermosetting resin composition be introduced into the polymer constituting the shell layer. The functional group may be, for example, a hydroxyl group, a carboxyl group or an epoxy group, and is preferably an epoxy group from the viewpoint of improving the compatibility with the epoxy resins.

The fine particulate rubber preferably has an average particle size of from 0.05 to 1 μm, from the viewpoint of achieving a good dispersibility.

The content of the fine particulate rubber is preferably from 3 to 15 parts by mass, more preferably from 3 to 13 parts by mass, and still more preferably from 3 to 10 parts by mass, when the total amount of the epoxy resins (the solid epoxy resin that is solid at 25° C. and the non-solid epoxy resin that is non-solid at 25° C.) contained in the thermosetting resin composition is taken as 100 parts by mass. When the content of the fine particulate rubber is within the range of from 3 to 15 parts by mass, the peel strength of a sheet-like electronic material including the thermosetting resin composition can be maintained at a high level without causing a decrease in the electrical insulation reliability after curing of the thermosetting resin composition.

The fine particulate rubber to be used is preferably a fine particulate rubber dispersed in the non-solid epoxy resin that is non-solid at 25° C., from the viewpoint of uniformly dispersing the rubber in the thermosetting resin composition.

Examples of the fine particulate rubber dispersed in the non-solid epoxy resin that is non-solid at 25° C. include MX-136, MX-153, MX-154, MX-170, MX-217, MX-257, MX-416, MX-451, MX-551, MX-960 and MX-965, manufactured by Kaneka Corporation.

### (Curing Agent)

The curing agent is preferably one that cures the epoxy resins. Examples of the curing agent include diaminodiphenylmethane (DDM), diaminodiphenyl sulfone (DDS), diaminodiphenyl ether (DDE), hexamethylenediamine, dicyandiamide and phenol novolac. Of these, dicyandiamide is preferred and diaminodiphenyl sulfone is more preferred, from the viewpoint of the ease of control of the curing reaction. Two or more kinds of the curing agents may be used, as well.

The equivalent of the curing agent is preferably from 0.3 to 0.8 equivalent, and more preferably from 0.3 to 0.6 equivalent, with respect to one equivalent of epoxy groups in the epoxy resins (the solid epoxy resin that is solid at 25° C. and the non-solid epoxy resin that is non-solid at 25° C.) contained in the thermosetting resin composition, from the viewpoint of achieving a good wiring embeddability, and the viewpoint of increasing the electrical insulation reliability after curing of the thermosetting resin composition.

### (Inorganic Filler)

Examples of the inorganic filler include aluminum hydroxide, magnesium hydroxide, and silica. Of these, magnesium hydroxide is preferred and aluminum hydroxide is more preferred, from the viewpoint of achieving a good flame retardancy and wiring embeddability, and the viewpoint of imparting tack-free properties required for quick pressing. Two or more kinds of the inorganic fillers may be used, as well.

From the viewpoint of achieving a good flame retardancy and wiring embeddability, and the viewpoint of imparting the tack-free properties, the content of the inorganic filler is preferably from 60 to 150 parts by mass, more preferably from 60 to 120 parts by mass, and still more preferably from 70 to 100 parts by mass, when the total amount of the epoxy resins (the solid epoxy resin that is solid at 25° C. and the non-solid epoxy resin that is non-solid at 25° C.) contained in the thermosetting resin composition is taken as 100 parts by mass.

### (Polycarbonate Diol-Derived Polyurethane)

The polycarbonate diol-derived polyurethane contained in the thermosetting resin composition of the embodiment includes at least one or more polycarbonate skeletons within the molecule. The number of the polycarbonate skeletons is not particularly limited as long as the polycarbonate diol-derived polyurethane is a polyurethane derived from a polycarbonate diol. When the polycarbonate diol-derived polyurethane includes at least one or more polycarbonate skeletons within the molecule, the hydrolysis of the polyurethane in a high temperature and high humidity environment after curing of the thermosetting resin composition is reduced. This makes it possible to ensure a high electrical insulation reliability after curing of the thermosetting resin composition. Further, membrane properties are imparted to the thermosetting resin composition according to the present disclosure, by containing the polycarbonate diol-derived polyurethane. This gives the flexibility required for a sheet-like electronic material such as a coverlay film or an adhesive sheet.

Examples of the polycarbonate diol include a polycarbonate diol represented by the following general formula (1).

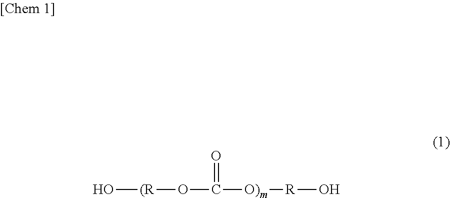

(In the general formula (1), R represents an alkylene group having from 1 to 10 carbon atoms, and m represents an integer from 1 to 20.)

It is preferred that R in the general formula (1) have from 1 to 10 carbon atoms, and m in the formula have from 1 to 20 carbon atoms, from the viewpoint of reducing the hydrolysis of the polyurethane in a high temperature and high humidity environment after curing of the thermosetting resin composition, and the viewpoint of improving the peel strength of a sheet-like electronic material including the thermosetting resin composition.

The polycarbonate diol-derived polyurethane is obtained by polymerizing a polycarbonate diol represented by the general formula (1) and a polyisocyanate. The polyisocyanate is not particularly limited, as long as the polyisocyanate is capable of reacting with a polycarbonate diol represented by the general formula (1) to form a polyurethane. Examples of the polyisocyanate include: aromatic diisocyanates such as tolylene-2,4-diisocyanate, 4-methoxy-1,3-phenylene diisocyanate, 2,4-diisocyanate diphenyl ether, 4,4′-methylenebis(phenylene diisocyanate) (MDI), 2,4′-methylenebis(phenylene diisocyanate), tolylene diisocyanate (TDI), xylylene diisocyanate (XDI) and 1,5-naphthalene diisocyanate; aliphatic diisocyanates such as methylene diisocyanate and 1,6-hexane diisocyanate (HDI); and alicyclic diisocyanates such as 1,4-cyclohexylene diisocyanate, 4,4′-methylenebis(cyclohexyl diisocyanate) and isophorone diisocyanate (IPDI).

The polyisocyanate may be a compound obtained by allowing any of these isocyanate compounds to react with a low molecular weight polyol or polyamine, so that the resulting compound has isocyanate groups as terminal functional groups. The polyisocyanate may be used singly, or two or more kinds of polyisocyanates may be used in combination. Isophorone diisocyanate is preferred from the viewpoints of heat resistance, flexibility and reactivity.

The polycarbonate diol-derived polyurethane is preferably acidic from the viewpoint of improving the peel strength of a sheet-like electronic material including the thermosetting resin composition. The polycarbonate diol-derived polyurethane that is acidic preferably contains a hydroxyl group, a sulfo group, or a carboxyl group in the molecular chain (mainly in a side chain) of the polyurethane. From the viewpoint of improving the reactivity with epoxy resins, and the viewpoint of improving the electrical properties of the thermosetting resin composition after curing, the polycarbonate diol-derived polyurethane that is acidic more preferably contains a carboxyl group. The acidity can be indicated by the acid value.

The acid value of the polycarbonate diol-derived polyurethane is from 10 to 30 mg KOH/g, and preferably from 10 to 25 mg KOH/g. When the acid value of the polycarbonate diol-derived polyurethane is from 10 to 30 mg KOH/g, a good wiring embeddability is achieved, and the peel strength of a sheet-like electronic material including the thermosetting resin composition is improved.

The acid value of the polycarbonate diol-derived polyurethane can be measured in accordance with JIS K0070.

From the viewpoint of increasing the peel strength of a sheet-like electronic material including the thermosetting resin composition, the content of the polycarbonate diol-derived polyurethane is preferably from 50 to 100 parts by mass, more preferably from 60 to 90 parts by mass, and still more preferably from 70 to 80 parts by mass, when the total amount of the epoxy resins (the solid epoxy resin that is solid at 25° C. and the non-solid epoxy resin that is non-solid at 25° C.) contained in the thermosetting resin composition is taken as 100 parts by mass.

The weight average molecular weight of the polycarbonate diol-derived polyurethane is preferably from 15,000 to 60,000, more preferably from 30,000 to 60,000, and still more preferably from 35,000 to 60,000. When the weight average molecular weight of the polycarbonate diol-derived polyurethane is from 15,000 to 60,000, the flexibility of the thermosetting resin composition after curing is improved, and a good wiring embeddability is achieved. The weight average molecular weight of the polycarbonate diol-derived polyurethane can be measured by gel permeation chromatography (GPC), using standard polystyrene having an average molecular weight of from about 500 to about 1,000,000.

### (Other Components)

The thermosetting resin composition of the embodiment may further contain one or more other additives and the like. Examples of the other additives include: imidazole accelerators such as 2-methylimidazole, N-benzyl-2-methylimidazole and 2-undecylimidazole; Lewis acid complexes such as boron trifluoride monoethylamine; curing accelerators such as polyamines and melamine resins; dispersants; softeners; anti-aging agents; pigments; dyes; and silane coupling agents.

### (Coverlay Film)

The coverlay film is used, for example, for protecting a wiring formed on a substrate. The coverlay film includes: a base material; and an adhesive layer laminated on one surface of the base material. The adhesive layer may be provided on both surfaces of a film-like base material. The use of the coverlay film having the above-described configuration enables to protect the wiring surfaces of a plurality of substrates with a single coverlay film. Further, it is possible to use a plurality of substrates to form a multilayered substrate.

The base material included in the coverlay film is a film-like base material. The base material has a thickness of from 2 to 75 μm.

Examples of the base material for the coverlay film include a polyimide (PI) base material, a polyamide (PA) base material, a polyethylene naphthalate (PEN) base material, a polyamideimide (PAI) base material, a polyethylene terephthalate (PET) base material, a polyphenylene sulfide (PPS) base material and a liquid crystal (LCP) base material. A polyimide (PI) base material is preferred from the viewpoints of flame retardancy, electrical insulation reliability, heat resistance and elastic modulus. Further, the surface of the base material can be subjected to a surface modification treatment, such as a corona treatment or a plasma treatment. This modifies the surface of the base material, and improves the adhesion between the adhesive layer and the base material.

The adhesive layer includes the thermosetting resin composition of the embodiment. The thickness of the adhesive layer after drying is from 5 to 50 μm. The cured state of the thermosetting resin composition forming the adhesive layer is a semi-cured state (Stage B).

The coverlay film is prepared by the following procedure. The thermosetting resin composition is dissolved in an organic solvent to prepare a solution containing the thermosetting resin composition. The thus prepared solution is coated on a film-like base material. Subsequently, the base material after coating is heated until the thermosetting resin composition reaches a semi-cured state (Stage B). After cooling, a coverlay film in which an adhesive layer including the thermosetting resin composition is formed on a film-like base material is obtained. The heating is performed under the conditions of a temperature of from 100 to 250° C. and a period of time from 5 seconds to 30 minutes, and the conditions are adjusted depending on the coating thickness.

Examples of the organic solvent include: alcohols such as methanol and ethanol; glycols such as ethylene glycol and propylene glycol; glycol monoalkyl ethers such as ethylene glycol monomethyl ether and ethylene glycol monoethyl ether; glycol dialkyl ethers such as ethylene glycol dimethyl ether and ethylene glycol diethyl ether; alkyl esters such as methyl acetate, ethyl acetate, propyl acetate, and methyl acetoacetate; ketones such as acetone, methyl ethyl ketone, methyl isobutyl ketone, and cyclohexanone; aromatic hydrocarbons such as benzene, toluene, xylene, and ethylbenzene; aliphatic hydrocarbons such as hexane, cyclohexane and octane; amides such as dimethylformamide, dimethylacetamide, and N-methylpyrrolidone; and cyclic ethers such as tetrahydrofuran and dioxane.

The coating apparatus is not particularly limited, and a known coater can be used. The coater may be, for example, a die coater, a comma coater, or a gravure coater.

When the adhesive layer included in the coverlay film has a thickness of 5 μm or less, the coverlay film can be prepared by the following procedure. First, the adhesive layer is formed on the surface of a mold release film that has been subjected to a mold release treatment, so as to achieve a thickness after drying of 5 μm. Thereafter, a film-like base material to be used for the coverlay film is separately prepared, and the base material and the mold release film on which the adhesive layer has been formed are laminated such that the surface of the base material is in contact with the surface of the adhesive layer. Subsequently, the resulting laminated body is heated and pressurized, and then the mold release film alone is peeled off. As a result, a coverlay film including the adhesive layer having a thickness of 5 μm can be obtained.

### (Adhesive Sheet)

The adhesive sheet is a sheet obtained by forming an adhesive including the thermosetting resin composition of the embodiment in the form of a sheet.

The adhesive layer constituting the adhesive sheet has a thickness of from 5 to 50 μm.

The adhesive sheet is prepared by the following procedure. The thermosetting resin composition is dissolved in an organic solvent to prepare a solution containing the thermosetting resin composition. The thus prepared solution is coated on the mold release-treated surface of a film-like base material that has been subjected to a mold release treatment. Subsequently, the base material after coating is heated until the thermosetting resin composition reaches a semi-cured state (Stage B). After cooling, an adhesive sheet in which an adhesive layer including the thermosetting resin composition is formed on a film-like base material is obtained. The heating is performed under the conditions of a temperature of from 100 to 250° C. and a period of time from 5 seconds to 30 minutes, and the conditions are adjusted depending on the coating thickness. The film-like base material is peeled off from the adhesive layer before use.

Examples of the mold release treatment agent used for the base material that has been subjected to a mold release treatment include a silicone treatment agent and a fluorine treatment agent.

Another configuration of the adhesive sheet may be, for example, a configuration in which the adhesive layer is formed on both surfaces of a film-like base material, from the viewpoint of increasing rigidity and electrical insulation reliability.

Yet another configuration of the adhesive sheet may be, for example, a prepreg in which a base material such as a woven fabric or a nonwoven fabric is impregnated with the thermosetting resin composition, from the viewpoint of increasing rigidity and electrical insulation reliability. The prepreg is prepared by the following procedure. First, a woven fabric or a nonwoven fabric including fibers such as glass fibers is prepared, as a base material. Subsequently, the thermosetting resin composition is dissolved in an organic solvent to prepare a solution containing the thermosetting resin composition. The base material is impregnated with the thus prepared solution. The base material taken out of the solution is heated until the thermosetting resin composition adherend to the base material reaches Stage B. After cooling, a prepreg in Stage B is obtained.

The adhesive sheet can be used as an interlayer adhesive for bonding substrates such as flexible printed wiring boards with one another. Further, the adhesive sheet can protect wiring by covering the wiring.

### (Flexible Printed Wiring Board)

The flexible printed wiring board includes: a substrate on which wiring is formed; and the coverlay film including a base material and the adhesive layer laminated on one surface of the base material, and the coverlay film is provided such that the adhesive layer is in contact with the surface of the substrate on which the wiring is formed.

The wiring formed on the substrate is, for example, a wiring formed by etching a copper layer of a copper-plated laminated plate or a copper-clad laminated plate. Another type of the wiring formed on the substrate may be a wiring formed by ink-jet printing using an electrically conductive ink. The material of the wiring may include another metal, such as silver or zinc, instead of copper.

The thickness of the substrate to be used for the flexible printed wiring board is from 15 to 200 μm from the viewpoint that the substrate has flexibility, but not particularly limited thereto.

The flexible printed wiring board is prepared by the following procedure. A substrate on which wiring is formed, and the coverlay film including a base material and the adhesive layer laminated on one surface of the base material, are prepared. Subsequently, the substrate and the coverlay film are laminated such that the adhesive layer is in contact with the surface of the substrate on which the wiring is formed, and the thus laminated coverlay film and substrate are heated and pressurized. As a result, the flexible printed wiring board is obtained. The heating and pressurization are performed under the conditions of a temperature of from 120 to 250° C., a period of time from 5 seconds to 120 minutes and a pressure of from 1 to 10 MPa, and the conditions are set depending on the laminated configuration.

### EXAMPLES

The present disclosure is described below in further detail with reference to the following Examples. The present disclosure is in no way limited to the following Examples.

The following components were used as the components to be contained in the resin compositions of Examples and Comparative Examples.

### (Epoxy Resins)

(1) Epoxy resin A: a biphenyl type epoxy resin that is solid at 25°, having an epoxy equivalent of 290 g/eq (NC3000H, manufactured by Nippon Kayaku Co., Ltd.);
(2) Epoxy resin B: a bisphenol A type epoxy resin that is non-solid at 25° C., having an epoxy equivalent of 190 g/eq (EPICLON 850, manufactured by DIC CORPORATION);
(3) Epoxy resin C: a fine particulate rubber-dispersed epoxy resin (phenol novolac type) that is non-solid at 25° C., having an epoxy equivalent of 231 g/eq and containing 25 parts by mass of a fine particulate rubber (polybutadiene rubber, average particle size: 0.1 μm) in 100 parts by mass of the total solid content (MX-217, manufactured by Kaneka Corporation); and
(4) Epoxy resin D: a fine particulate rubber-dispersed epoxy resin (bisphenol A type) that is non-solid at 25° C., having an epoxy equivalent of 294 g/eq and containing 37 parts by mass of a fine particulate rubber (polybutadiene rubber, average particle size: 0.1 μm) in 100 parts by mass of the total solid content (MX-257, manufactured by Kaneka Corporation).

### (Curing Agent)

Diaminodiphenyl sulfone: amine value: 62 g/eq (3,3′-DAS, manufactured by Konishi Chemical Ind. Co., Ltd.).

### (Inorganic Filler)

Aluminum hydroxide (BF013, manufactured by Nippon Light Metal Company, Ltd.).

### (Polycarbonate Diol-Derived Polyurethane)

### [Synthesis of Polycarbonate Diol-Derived Polyurethane A]

To a one-liter flask equipped with a stirrer, a thermometer and a cooling tube, 250.0 g of (a) a carbonate polyol (ETERNACOLL (registered trademark) UH-100 (hydroxyl value: 112 mg KOH/g), manufactured by Ube Industries, Ltd.), 32.1 g of (b) dimethylolpropanoic acid and 104.2 g of (c) isophorone diisocyanate were introduced. Further, dimethylacetamide in an amount corresponding to 10% by mass of the total amount of (a), (b), and (c), and toluene in an amount corresponding to 45% by mass of the total amount of (a), (b) and (c) were added to the flask, as solvents, and the resulting mixture was stirred at 100° C. Thereafter, the mixture was allowed to react until there was no remaining NCO groups, and then methyl ethyl ketone in an amount corresponding to 45% by mass of the total amount of (a), (b), and (c) was added to the flask, to obtain a polyurethane resin solution with a resin content of 45% by mass.

Polycarbonate diol-derived polyurethanes B to J were synthesized in the same manner as in the synthesis of the polycarbonate diol-derived polyurethane A, varying the amounts to be added of the respective components, as illustrated in Table 1 below.

TABLE 1

| | SYNTHESIS | SYNTHESIS | SYNTHESIS | SYNTHESIS | SYNTHESIS |
|---|---|---|---|---|---|
| | EXAMPLE 1 | EXAMPLE 2 | EXAMPLE 3 | EXAMPLE 4 | EXAMPLE 5 |
| | POLYURE- | POLYURE- | POLYURE- | POLYURE- | POLYURE- |
| | THANE A | THANE B | THANE C | THANE D | THANE E |
| (a) | 250.0 | 250.0 | 250.0 | 250.0 | 250.0 |
| POLYCARBONATE | | | | | |
| DIOL | | | | | |
| (b) | 32.1 | 26.4 | 16.7 | 7.7 | 4.0 |
| DIMETHYLOL | | | | | |
| PROPANOIC | | | | | |
| ACID | | | | | |
| (c) | 104.2 | 95.2 | 79.8 | 65.4 | 59.6 |
| ISOPHORONE | | | | | |
| DIIOSOCYANATE | | | | | |
| NCO/OH | 0.96 | 0.96 | 0.96 | 0.96 | 0.96 |
| NUMBER | 24,000 | 20,000 | 21,000 | 16,000 | 15,000 |
| AVERAGE | | | | | |
| MOLECULAR | | | | | |
| WEIGHT | | | | | |
| WEIGHT | 46,000 | 37,000 | 38,000 | 29,000 | 24,000 |
| AVERAGE | | | | | |
| MOLECULAR | | | | | |
| WEIGHT | | | | | |
| ACID VALUE | 35.1 | 29.5 | 21.0 | 10.2 | 5.5 |
| (mgKOH/g) | | | | | |
| | SYNTHESIS | SYNTHESIS | SYNTHESIS | SYNTHESIS | SYNTHESIS |
| | EXAMPLE 6 | EXAMPLE 7 | EXAMPLE 8 | EXAMPLE 9 | EXAMPLE 10 |
| | POLYURE- | POLYURE- | POLYURE- | POLYURE- | POLYURE- |
| | THANE F | THANE G | THANE H | THANE I | THANE J |
| (a) | 250.0 | 250.0 | 250.0 | 250.0 | 250.0 |
| POLYCARBONATE | | | | | |
| DIOL | | | | | |
| (b) | 16.7 | 16.7 | 16.7 | 16.7 | 16.7 |
| DIMETHYLOL | | | | | |
| PROPANOIC | | | | | |
| ACID | | | | | |
| (c) | 70.6 | 74.8 | 81.4 | 82.1 | 82.3 |
| ISOPHORONE | | | | | |
| DIIOSOCYANATE | | | | | |
| NCO/OH | 0.85 | 0.90 | 0.98 | 0.99 | 0.99 |
| NUMBER | 8,000 | 10,300 | 29,500 | 33,000 | 35,000 |
| AVERAGE | | | | | |
| MOLECULAR | | | | | |
| WEIGHT | | | | | |
| WEIGHT | 14,000 | 15,200 | 49,500 | 60,000 | 63,000 |
| AVERAGE | | | | | |
| MOLECULAR | | | | | |
| WEIGHT | | | | | |
| ACID VALUE | 20.9 | 20.4 | 20.5 | 20.4 | 20.4 |
| (mgKOH/g) | | | | | |

The values of (a), (b), and (c) in the Table each indicate the mass (g) of each compound.

### (Other Flexible Components)

(1) Polyester polyurethane K: number average molecular weight: 13,000; acid value: 35 mg KOH/g (UR-3500, manufactured by Toyobo Co., Ltd), and
(2) Acrylonitrile-butadiene rubber L: acid value: 40 mg KOH/g (JSR XER-32C, manufactured by JSR Corporation).

In Examples and Comparative Examples, respective evaluations and measurements were performed by the following methods.

### <Peeling Strength (Peel Strength)>

### (1) Sample Preparation Procedure

### (1-1) Preparation of Coverlay Film

On one surface of a polyimide film (APICAL 12.5NPI, manufactured by Kaneka Corporation) with a thickness of 12.5 μm, the resin composition for forming an adhesive layer was coated to a thickness after drying of 25 μm, and dried at 160° C. for 10 minutes until the coated composition reached a semi-cured state (Stage B). Thereafter, a mold release PET film was laminated on the adhesive layer side of the film at 100° C., to obtain a coverlay film with a mold release PET film.

### (1-2) Preparation of Sample for Measurement

The mold release PET film was peeled off from the coverlay film prepared in (1-1). Subsequently, the coverlay film and a rolled copper foil (BHY-22B-T, thickness: 35 μm, manufactured by JX Nippon Mining & Metals Corporation) were laminated such that the surface of the adhesive layer was in contact with the glossy surface of the foil, and then heated and pressurized under the conditions of 185° C., 3.0 MPa and 60 seconds. Thereafter, the thus laminated coverlay film and foil were heated in an oven set to 160° C. for one hour, to obtain a sample for measurement.

### (2) Measurement Method

The sample for measurement prepared in (1-2) was cut into a piece with a width of 10 mm and a length of 100 mm, and the peeling strength in the 180° direction (the direction parallel to the surface of the sample for measurement) of the sample was measured using an Autograph, AGS-500, manufactured by SHIMADZU Corporation, under the following conditions.

The measurement was performed by copper foil peeling, at a test speed of 50 mm/min.

The evaluation criteria were as follows.

Excellent: The peeling strength was 10N/cm or more.

Good: The peeling strength was 7N/cm or more but less than 10N/cm.

Poor: The peeling strength was less than 7N/cm.

### <Electrical Insulation Reliability (BHAST)>

### (1) Sample Preparation Procedure

### (1-1) Preparation of Coverlay Film

On one surface of a polyimide film (APICAL 12.5NPI, manufactured by Kaneka Corporation) with a thickness of 12.5 μm, the resin composition for forming an adhesive layer was coated to a thickness after drying of 15 μm, and dried at 160° C. for 10 minutes until the coated composition reached a semi-cured state (Stage B). Thereafter, a mold release PET film was laminated on the adhesive layer side of the film at 100° C., to obtain a coverlay film with a mold release PET film.

### (1-2) Preparation of Adherend

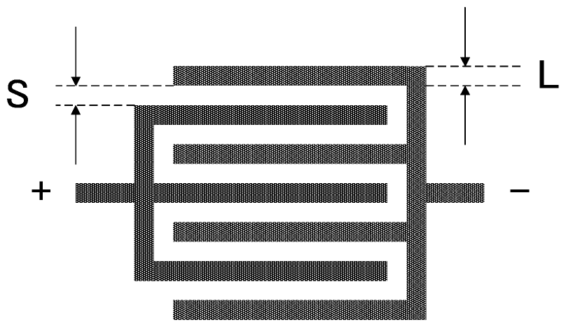

The glossy copper foil surface of a two-layer substrate (PNS H0509RAC, manufactured by Arisawa Mfg. Co., Ltd.) was etched to obtain an adherend on which a wiring pattern (hereinafter, expressed as L/S=20/20) whose wiring width (L) and wiring spacing(S) illustrated in FIG. 1 are each 20 μm was formed.

### (1-3) Preparation of Sample for Measurement

The mold release PET film was peeled off from the coverlay film prepared in (1-1). Subsequently, the coverlay film and the adherend prepared in (1-2) were laminated such that the surface of the adhesive layer faced the surface of the adherend on which the wiring had been formed, and then heated and pressurized under the conditions of 185° C., 3.0 MPa and 60 seconds. Thereafter, the thus laminated coverlay film and adherend were heated in an oven set to 160° C. for one hour, to obtain a sample for measurement.

### (2) Measurement Method

One end and the other end of the wiring were connected to one end and the other end of the wiring of a device, respectively, such that a voltage is applied to the wiring pattern. After maintaining the voltage application for 200 hours under the conditions of 110° C., 85% RH and DC 50V after the connection, the presence or absence of short circuits and of a change in appearance, such as dendrites, was confirmed by visual observation and evaluated.

The evaluation criteria were as follows.

Excellent: The occurrence of short circuits and a change in appearance were not observed, after 200 hours.

Good: The occurrence of short circuits was not observed but there was a change in appearance, after 200 hours.

Poor: The occurrence of short circuits and a change in appearance were both observed, before reaching 200 hours.

### <Wiring Embeddability>

### (1) Sample Preparation Procedure

### (1-1) Preparation of Coverlay Film

On one surface of a polyimide film (APICAL 12.5NPI, manufactured by Kaneka Corporation) with a thickness of 12.5 μm, the resin composition for forming an adhesive layer was coated to a thickness after drying of 15 μm, and heated at 160° C. for 10 minutes until the coated composition reached a semi-cured state (Stage B). Thereafter, a mold release PET film was laminated on the adhesive layer side of the film at 100° C., to obtain a coverlay film with a mold release PET film.

### (1-2) Preparation of Adherend

The glossy copper foil surface of a two-layer substrate including an electrolytic copper foil (thickness: 18 μm, manufactured by JX Nippon Mining & Metals Corporation) on the rough surface of which foil a polyimide layer with a thickness of 25 μm had been formed, was etched to obtain an adherend in which a wiring pattern of L/S=50/50, 60/60, 70/70, 80/80, 90/90 or 100/100 was formed.

### (2) Evaluation Method

The mold release PET film was peeled off from the coverlay film prepared in (1-1). Subsequently, the coverlay film and the adherend prepared in (1-2) were laminated such that the surface of the adhesive layer faced the surface of the adherend on which the wiring had been formed, and then subjected to thermocompression bonding (quick pressing) under the conditions of 185° C., 3.0 MPa and 30 seconds, or under the conditions of 185° C., 3.0 MPa and 60 seconds. Thereafter, the thus laminated coverlay film and adherend were heated in an oven set to 160° C. for one hour. After cooling the laminated sample, the sample was cut perpendicular to the longitudinal direction of the wiring. After polishing the cross section, the cross section was observed with an optical microscope, and whether or not the sample has a good wiring embeddability was evaluated.

The evaluation criteria were as follows.

Excellent: The resin spread into and filled the grooves between the wiring in a molding time of quick pressing of 30 seconds.

Good: The resin did not spread into and fill the grooves between the wiring in a molding time of quick pressing of 30 seconds, but did spread into and fill the grooves in 60 seconds.

Poor: The resin did not spread into and fill the grooves between the wiring, either in a molding time of quick pressing of 30 seconds or 60 seconds.

### Example 1

Seventy parts by mass of the epoxy resin A and 30 parts by mass of the epoxy resin C were introduced into a container, so that the total parts by mass of the epoxy resins was 100 parts by mass. To the epoxy resins, 10.4 parts by mass of the curing agent, 75 parts by mass of the polycarbonate diol-derived polyurethane B, 90 parts by mass of the aluminum hydroxide, and 400 parts by mass of methyl ethyl ketone as an organic solvent, were added. Then the resulting mixture was stirred at room temperature, to obtain a thermosetting resin composition.

### Example 2 to Example 13 and Comparative Example 1 to Comparative Example 11

The thermosetting resin compositions of Examples and Comparative Examples were obtained in the same manner as in Example 1, varying the type and the content of each component as illustrated in Tables 2 and 3. The unit of the content of each component in the tables is parts by mass unless otherwise specified.

TABLE 2

| | | | EXAM- | EXAM- | EXAM- | EXAM- | EXAM- | EXAM- | EXAM- |
|---|---|---|---|---|---|---|---|---|---|
| | | | PLE 1 | PLE 2 | PLE 3 | PLE 4 | PLE 5 | PLE 6 | PLE 7 |
| COMPOSITION | EPOXY RESIN (A) | | 70 | 70 | 70 | 70 | 85 | 60 | 60 |
| | EPOXY RESIN (B) | | | | | | | | |
| | EPOXY RESIN (C) | | 30 | 30 | 30 | 30 | 15 | 40 | |
| | EPOXY RESIN (D) | | | | | | | | 40 |
| | FINE PARTICULATE RUBBER (PARTS | | 7.5 | 7.5 | 7.5 | 7.5 | 3.8 | 10.0 | 14.8 |
| | CONTAINED IN EPOXY RESIN) | | | | | | | | |
| | CURING | NUMBER OF EQUIVALENT | 0.45eq | 0.45eq | 0.45eq | 0.45eq | 0.45eq | 0.45eq | 0.45eq |
| | AGENT | PARTS BY MASS (*) | 10.4 | 10.4 | 10.4 | 10.4 | 10.0 | 10.6 | 9.6 |

| | | | | | | | | |
|---|---|---|---|---|---|---|---|---|
| | INORGANIC FILLER | 90 | 90 | 90 | 90 | 90 | 90 | 90 |
| | POLYCARBONATE DIOL-DERIVED | | | | | | | |
| | POLYURETHANE A | | | | | | | |
| | POLYCARBONATE DIOL-DERIVED | 75 | | | | | | |
| | POLYURETHANE B | | | | | | | |
| | POLYCARBONATE DIOL-DERIVED | | 50 | 75 | 100 | 75 | 75 | 75 |
| | POLYURETHANE C | | | | | | | |
| | POLYCARBONATE DIOL-DERIVED | | | | | | | |
| | POLYURETHANE D | | | | | | | |
| | POLYCARBONATE DIOL-DERIVED | | | | | | | |
| | POLYURETHANE E | | | | | | | |
| | POLYCARBONATE DIOL-DERIVED | | | | | | | |
| | POLYURETHANE F | | | | | | | |
| | POLYCARBONATE DIOL-DERIVED | | | | | | | |
| | POLYURETHANE G | | | | | | | |
| | POLYCARBONATE DIOL-DERIVED | | | | | | | |
| | POLYURETHANE H | | | | | | | |
| | POLYCARBONATE DIOL-DERIVED | | | | | | | |
| | POLYURETHANE I | | | | | | | |
| | POLYCARBONATE DIOL-DERIVED | | | | | | | |
| | POLYURETHANE J | | | | | | | |
| | POLYESTER POLYURETHANE K | | | | | | | |
| | ACRYLONITRILE-BUTADIENE RUBBER L | | | | | | | |
| EVALUATION | PEEL STRENGTH | Excellent | Good | Excellent | Excellent | Good | Excellent | Excellent |
| | ELECTRICAL INSULATION | Excellent | Excellent | Excellent | Excellent | Excellent | Good | Good |
| | RELIABILITY (BHAST) | | | | | | | |
| | WIRING EMBEDDABILITY | Good | Good | Excellent | Good | Excellent | Good | Good |

| | | EXAM- | EXAM- | EXAM- | EXAM- | EXAM- | EXAM- |
|---|---|---|---|---|---|---|---|
| | | PLE 8 | PLE 9 | PLE 10 | PLE 11 | PLE 12 | PLE 13 |
| COMPOSITION | EPOXY RESIN (A) | 70 | 70 | 70 | 70 | 70 | 70 |
| | EPOXY RESIN (B) | | | | | | |
| | EPOXY RESIN (C) | 30 | 30 | 30 | 30 | 30 | 30 |
| | EPOXY RESIN (D) | | | | | | |
| | FINE PARTICULATE RUBBER (PARTS | 7.5 | 7.5 | 7.5 | 7.5 | 7.5 | 7.5 |
| | CONTAINED IN EPOXY RESIN) | | | | | | |

| | | | | | | | |
|---|---|---|---|---|---|---|---|
| CURING | NUMBER OF EQUIVALENT | 0.45eq | 0.45eq | 0.45eq | 0.45eq | 0.45eq | 0.45eq |
| AGENT | PARTS BY MASS (*) | 10.4 | 10.4 | 10.4 | 10.4 | 10.4 | 10.4 |

| | | | | | | | |
|---|---|---|---|---|---|---|---|
| | INORGANIC FILLER | 60 | 150 | 90 | 90 | 90 | 90 |
| | POLYCARBONATE DIOL-DERIVED | | | | | | |
| | POLYURETHANE A | | | | | | |
| | POLYCARBONATE DIOL-DERIVED | | | | | | |
| | POLYURETHANE B | | | | | | |
| | POLYCARBONATE DIOL-DERIVED | 75 | 75 | | | | |
| | POLYURETHANE C | | | | | | |
| | POLYCARBONATE DIOL-DERIVED | | | 75 | | | |
| | POLYURETHANE D | | | | | | |
| | POLYCARBONATE DIOL-DERIVED | | | | | | |
| | POLYURETHANE E | | | | | | |
| | POLYCARBONATE DIOL-DERIVED | | | | | | |
| | POLYURETHANE F | | | | | | |
| | POLYCARBONATE DIOL-DERIVED | | | | 75 | | |
| | POLYURETHANE G | | | | | | |
| | POLYCARBONATE DIOL-DERIVED | | | | | 75 | |
| | POLYURETHANE H | | | | | | |
| | POLYCARBONATE DIOL-DERIVED | | | | | | 75 |
| | POLYURETHANE I | | | | | | |
| | POLYCARBONATE DIOL-DERIVED | | | | | | |
| | POLYURETHANE J | | | | | | |
| | POLYESTER POLYURETHANE K | | | | | | |
| | ACRYLONITRILE-BUTADIENE | | | | | | |
| | RUBBER L | | | | | | |
| EVALUATION | PEEL STRENGTH | Excellent | Good | Excellent | Good | Excellent | Excellent |
| | ELECTRICAL INSULATION | Excellent | Excellent | Good | Excellent | Excellent | Excellent |
| | RELIABILITY (BHAST) | | | | | | |
| | WIRING EMBEDDABILITY | Good | Good | Excellent | Excellent | Good | Good |

(*) The amount in parts by mass of the curing agent is adjusted such that the equivalent of the curing agent with respect to one equivalent of epoxy groups is 0.45eq.

TABLE 3

| | | | COMPAR- | COMPAR- | COMPAR- | COMPAR- | COMPAR- | COMPAR- |
|---|---|---|---|---|---|---|---|---|
| | | | ATIVE | ATIVE | ATIVE | ATIVE | ATIVE | ATIVE |
| | | | EXAM- | EXAM- | EXAM- | EXAM- | EXAM- | EXAM- |
| | | | PLE 1 | PLE 2 | PLE 3 | PLE 4 | PLE 5 | PLE 6 |
| COMPOSITION | EPOXY RESIN (A) | | 70 | 70 | 70 | 70 | 70 | 70 |
| | EPOXY RESIN (B) | | | | | | | |
| | EPOXY RESIN (C) | | 30 | 30 | 30 | 30 | 30 | 30 |
| | EPOXY RESIN (D) | | | | | | | |
| | FINE PARTICULATE RUBBER (PARTS | | 7.5 | 7.5 | 7.5 | 7.5 | 7.5 | 7.5 |
| | CONTAINED IN EPOXY RESIN) | | | | | | | |
| | CURING | NUMBER OF EQUIVALENT | 0.45eq | 0.45eq | 0.45eq | 0.45eq | 0.45eq | 0.45eq |
| | AGENT | PARTS BY MASS (*) | 10.4 | 10.4 | 10.4 | 10.4 | 10.4 | 10.4 |

| | | | | | | | |
|---|---|---|---|---|---|---|---|
| | INORGANIC FILLER | 90 | 90 | 90 | 90 | 90 | 90 |
| | POLYCARBONATE DIOL-DERIVED | 75 | | | | | |
| | POLYURETHANE A | | | | | | |
| | POLYCARBONATE DIOL-DERIVED | | | | | | |
| | POLYURETHANE B | | | | | | |
| | POLYCARBONATE DIOL-DERIVED | | | | | | |
| | POLYURETHANE C | | | | | | |
| | POLYCARBONATE DIOL-DERIVED | | | | | | |
| | POLYURETHANE D | | | | | | |
| | POLYCARBONATE DIOL-DERIVED | | 75 | | | | |
| | POLYURETHANE E | | | | | | |
| | POLYCARBONATE DIOL-DERIVED | | | 75 | | | |
| | POLYURETHANE F | | | | | | |
| | POLYCARBONATE DIOL-DERIVED | | | | | | |
| | POLYURETHANE G | | | | | | |
| | POLYCARBONATE DIOL-DERIVED | | | | | | |
| | POLYURETHANE H | | | | | | |
| | POLYCARBONATE DIOL-DERIVED | | | | | | |
| | POLYURETHANE I | | | | | | |
| | POLYCARBONATE DIOL-DERIVED | | | | 75 | | |
| | POLYURETHANE J | | | | | | |
| | POLYESTER POLYURETHANE K | | | | | 75 | |
| | ACRYLONITRILE-BUTADIENE | | | | | | 75 |
| | RUBBER L | | | | | | |
| EVALUATION | PEEL STRENGTH | Excellent | Poor | Poor | Excellent | Excellent | Excellent |
| | ELECTRICAL INSULATION | Excellent | Good | Poor | Excellent | Good | Poor |
| | RELIABILITY (BHAST) | | | | | | |
| | WIRING EMBEDDABILITY | Poor | Excellent | Good | Poor | Poor | Good |

| | | COMPAR- | COMPAR- | COMPAR- | COMPAR- | COMPAR- |
|---|---|---|---|---|---|---|
| | | ATIVE | ATIVE | ATIVE | ATIVE | ATIVE |
| | | EXAM- | EXAM- | EXAM- | EXAM- | EXAM- |
| | | PLE 7 | PLE 8 | PLE 9 | PLE 10 | PLE 11 |
| COMPOSITION | EPOXY RESIN (A) | 90 | | 100 | 70 | 70 |
| | EPOXY RESIN (B) | | | | | 30 |
| | EPOXY RESIN (C) | 10 | 100 | | 30 | |
| | EPOXY RESIN (D) | | | | | |
| | FINE PARTICULATE RUBBER (PARTS | 2.5 | 25.0 | 0.0 | 7.5 | 0.0 |
| | CONTAINED IN EPOXY RESIN) | | | | | |

| | | | | | | |
|---|---|---|---|---|---|---|
| CURING | NUMBER OF EQUIVALENT | 0.45eq | 0.45eq | 0.45eq | 0.45eq | 0.45eq |
| AGENT | PARTS BY MASS (*) | 9.9 | 12.1 | 9.6 | 10.4 | 11.2 |

| | | | | | | |
|---|---|---|---|---|---|---|
| | INORGANIC FILLER | 90 | 90 | 90 | | 90 |
| | POLYCARBONATE DIOL-DERIVED | | | | | |
| | POLYURETHANE A | | | | | |
| | POLYCARBONATE DIOL-DERIVED | | | | | |
| | POLYURETHANE B | | | | | |
| | POLYCARBONATE DIOL-DERIVED | 75 | 75 | 75 | 75 | 75 |
| | POLYURETHANE C | | | | | |
| | POLYCARBONATE DIOL-DERIVED | | | | | |
| | POLYURETHANE D | | | | | |
| | POLYCARBONATE DIOL-DERIVED | | | | | |
| | POLYURETHANE E | | | | | |
| | POLYCARBONATE DIOL-DERIVED | | | | | |
| | POLYURETHANE F | | | | | |
| | POLYCARBONATE DIOL-DERIVED | | | | | |
| | POLYURETHANE G | | | | | |
| | POLYCARBONATE DIOL-DERIVED | | | | | |
| | POLYURETHANE H | | | | | |
| | POLYCARBONATE DIOL-DERIVED | | | | | |
| | POLYURETHANE I | | | | | |
| | POLYCARBONATE DIOL-DERIVED | | | | | |
| | POLYURETHANE J | | | | | |
| | POLYESTER POLYURETHANE K | | | | | |
| | ACRYLONITRILE-BUTADIENE | | | | | |
| | RUBBER L | | | | | |
| EVALUATION | PEEL STRENGTH | Poor | Excellent | Poor | Good | Poor |
| | ELECTRICAL INSULATION | Excellent | Good | Excellent | Good | Excellent |
| | RELIABILITY (BHAST) | | | | | |
| | WIRING EMBEDDABILITY | Excellent | Poor | Excellent | Poor | Excellent |

(*) The amount in parts by mass of the curing agent is adjusted such that the equivalent of the curing agent with respect to one equivalent of epoxy groups is 0.45eq.

As illustrated in Table 2, the thermosetting resin compositions of Examples 1 to 13 had an excellent workability (wiring embeddability) by quick pressing, and an excellent electrical insulation reliability in BHAST. Further, no swelling or peeling was observed in the thermosetting resin compositions of Examples 1 to 13 even when brought into contact with a solder bath at 260° C. for 60 seconds or more, in the evaluation of solder heat resistance, exhibiting an excellent solder heat resistance. All of the thermosetting resin compositions of Examples had a V-0 rating in the UL94 standard, which is required for a sheet-like electronic material in the evaluation of flame retardancy.

In the evaluation of solder heat resistance, each sample for measurement (laminated plate) prepared by (1) Sample Preparation Procedure in the section of <Peeling Strength (Peel Strength)>was floated on a solder bath at 260° C. such that the copper foil surface of the laminated plate was in contact with the solder bath. Each sample was maintained in that state for 60 seconds or more, and the presence or absence of swelling and peeling was confirmed by visual observation.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

What is claimed is:

1. A thermosetting resin composition, comprising:
a solid epoxy resin that is solid at 25° C.;
a non-solid epoxy resin that is non-solid at 25° C.;
a fine particulate rubber dispersed in the non-solid epoxy resin;
a curing agent;
an inorganic filler; and
a polycarbonate diol-derived polyurethane, wherein
a content of the fine particulate rubber is from 3 to 15 parts by mass with respect to total parts by mass of the solid epoxy resin and the non-solid epoxy resin,
an acid value of the polycarbonate diol-derived polyurethane is from 10 to 30 mg KOH/g, and
a weight average molecular weight of the polycarbonate diol-derived polyurethane is from 15,000 to 60,000.

2. The thermosetting resin composition according to claim 1, wherein the fine particulate rubber includes core-shell polymer particles.

3. The thermosetting resin composition according to claim 1, wherein the fine particulate rubber and the non-solid epoxy resin are contained in an amount of from 15 to 40 parts by mass, when the total parts by mass of the solid epoxy resin and the non-solid epoxy resin is taken as 100 parts by mass.

4. The thermosetting resin composition according to claim 1, wherein the polycarbonate diol-derived polyurethane is contained in an amount of from 50 to 100 parts by mass, when the total parts by mass of the solid epoxy resin and the non-solid epoxy resin is taken as 100 parts by mass.

5. The thermosetting resin composition according to claim 1, wherein the inorganic filler is contained in an amount of from 60 to 150 parts by mass, when the total parts by mass of the solid epoxy resin and the non-solid epoxy resin is taken as 100 parts by mass.

6. A coverlay film, comprising:
a base material; and
an adhesive layer laminated on one surface of the base material,
wherein an adhesive of the adhesive layer includes the thermosetting resin composition according to claim 1.

7. An adhesive sheet comprising the thermosetting resin composition according to claim 1.

8. A flexible printed wiring board, comprising:
a substrate on which wiring is formed; and
a coverlay film including
a base material, and
an adhesive layer laminated on one surface of the base material, wherein
the coverlay film is provided such that the adhesive layer is in contact with the surface of the substrate on which the wiring is formed, and
the coverlay film is the coverlay film according to claim 6.
